(19) United States
(12) Patent Application Publication
(10) Pub. No.: US 2013/0099789 A1
(43) Pub. Date: Apr. 25, 2013

(54) RESONANCE CIRCUIT HAVING A VARIABLE RESONANCE FREQUENCY

(71) Applicants: Mohamed Yahia Benslimane, Nordborg (DK); Peter Gravesen, Nordborg (DK)

(72) Inventors: Mohamed Yahia Benslimane, Nordborg (DK); Peter Gravesen, Nordborg (DK)

(73) Assignee: DANFOSS POLYPOWER A/S, Nordborg (DK)

(21) Appl. No.: 13/699,820

(22) PCT Filed: May 26, 2011
(86) PCT No.: PCT/DK11/00051

§ 371 Date: Dec. 20, 2012

(30) Foreign Application Priority Data
May 27, 2010 (DK) PA 2010 00466

(51) Int. Cl. G01R 33/36

(52) U.S. Cl. CPC G01R 33/3635
USPC 324/322

(57) ABSTRACT

A resonance circuit with a variable resonance frequency provided by a variable capacitor having compliant electrodes arranged on a deformable sheet. When the sheet is deformed the capacitance is varied. Further a sensing element comprising the resonance circuit and a sensing system comprising at least one sensing element, a sending unit and a receiving unit. Suitable for mass production. Provides wireless sensing system being cost effective to manufacture. May be used for low cost products, such as toys. May also be used for monitoring displacements in structures, e.g. cracks in wall structures. Further a positions sensitive pressure sensor with pressure sensors arranged on a two-dimensional structure.

### CROSS REFERENCE TO RELATED APPLICATIONS

This application is entitled to the benefit of and incorporates by reference essential subject matter disclosed in International Patent Application No. PCT/DK2011/000051 filed on May 26, 2011 and Danish Patent Application No. PA 2010 00466 filed May 27, 2010.

### FIELD OF THE INVENTION

The present invention relates to a resonance circuit in which the resonance frequency is variable. The present invention further relates to a sensing element comprising such a resonance circuit and a sensing system comprising such a sensing element. Finally, the present invention relates to a position sensitive pressure sensor comprising a plurality of pressure sensitive elements.

### BACKGROUND OF THE INVENTION

US 2003/0139690 A1 describes a device for in vivo measurement of pressure and pressure variations in or on bones. The device is composed of an implantable probe and an evaluating unit, the probe comprising an oscillating circuit including a capacitor in the form of a pressure sensor and a coil. The evaluating unit comprises a resonance oscillating circuit capable of detecting the natural frequency of the oscillating circuit. The natural frequency is variable according to variations of a dimension of the capacitor caused by pressure variations. The variations of a dimension of the capacitor are caused by a deformation of a membrane of the capacitor. The pressure sensor is spatially separated from the coil and connected to the latter by an electric conductor. This allows for small dimensions of the implantable pressure sensor while ensuring that a clear signal can be transmitted over a relatively long distance.

It is a disadvantage of the device described in US 2003/0139690 A1 that the variations in the natural frequency is caused by the deformation of a membrane of the capacitor, because the device is thereby relatively difficult and expensive to manufacture.

### SUMMARY OF THE INVENTION

It is, thus, an object of the present invention to provide a resonance circuit having a variable resonance frequency and which is relatively cheap and easy to manufacture.

It is a further object of the present invention to provide a resonance circuit having a variable resonance frequency and which is suitable for mass production.

It is an even further object of the present invention to provide a wireless sensing system which is cost effective to manufacture.

It is an even further object of the present invention to provide a position sensitive pressure sensor which is cost effective to manufacture.

It is an even further object of the present invention to provide sensor comprising a resonance circuit, being capable of changing its resonance frequency in response to a pressure exerted on the sensor.

It is an even further object of the present invention to provide sensor comprising a resonance circuit, being capable of changing its resonance frequency in response to a pressure exerted on the sensor, and where the change in resonance frequency is transformed into some actuation.

It is an even further object of the present invention to provide system of sensors comprising resonance circuits, being capable of registering a distribution of pressure across an area.

It is an even further object of the present invention to provide sensor comprising a resonance circuit, being capable of changing its resonance frequency in response to a displacement.

It is an even further object of the present invention to provide sensor comprising a resonance circuit, being capable of changing its resonance frequency in response to a strain.

According to a first aspect of the present invention the above and other objects are fulfilled by providing a resonance circuit comprising:
a coil,
a capacitor comprising a set of compliant electrodes arranged on a deformable sheet in such a way that deformation of the deformable sheet causes the capacitance of the capacitor to vary, thereby varying the resonance frequency of the resonance circuit.

The coil and the capacitor in combination form the resonance circuit. The resonance frequency of such a resonance circuit is determined by the inductance, L, of the coil and the capacitance, C, of the capacitor, and is given by

$$f = \frac{1}{2 π \sqrt{LC}} .$$

Since the capacitance, C, of the capacitor varies as the deformation applied to the deformable material varies, the resonance frequency will also vary due to the above relation.

In the present context the term ‘compliant electrodes’ should be interpreted as electrodes which may be subject to a change in size along at least one dimension. Thus, a compliant electrode may, e.g., be stretched in one or more directions, and it should be able to follow, or at least not prevent, deformations of the deformable sheet at least to some extent.

The fact that the compliant electrodes of the capacitor are arranged on a deformable sheet allows for the possibility of providing a resonance circuit in which the manufacturing process is kept at a cost effective level. Thus, resonance circuits as defined above may be manufactured in the form of large sheets or long tapes or strips. The sheets/tapes/strips may subsequently be cut out in desired sizes and shapes to meet specific needs. The resonance circuits may furthermore be attached to larger objects, thereby forming elements which are, e.g., suitable for sensing a pressure applied to the object or a displacement occurring in the object, or the object may be used as a wireless ‘button’, e.g. for activating a remote device. Thereby the resonance circuits are very well suited for mass production, thereby allowing production costs to be kept low.

In the present context the term ‘deformable sheet’ should be interpreted to mean a piece of material which is dimensioned in such a way that the size in one dimension is substantially smaller than the size in the remaining two dimensions, i.e. a relatively flat object. Furthermore, the deformable sheet should be made from a material which, when in a state where no external pressure is applied to the material, may be deformed along at least one dimension by applying a pressure to the material along that dimension, the deformation causing an object made from the material to become smaller along that dimension, the deformation further causing the size of the object to increase along another dimension, thereby substantially preserving the original volume of the material. Furthermore, stretching an object made from the material along one dimension, thereby increasing the size of the object along that dimension will result in the size along one or both of the remaining dimensions to decrease. Thus, the term ‘deformable’ should be interpreted as an inherent property of the material.

Preferably, the deformable sheet is compliant in the sense that it may be rolled or bent in such a way that the resonance circuit may be given a desired shape or fitted onto an object having a specific shape, and in such a way that the shape of the resonance circuit may be changed as desired. Preferably, the deformable sheet is made from an elastomeric material, such as a silicon elastomer, e.g. elastosil625. However, any elastomeric material having appropriate properties in terms of deformability could be used. Alternatively, the deformable sheet may be relatively stiff, i.e. it may be adapted to at least substantially preserve its shape, at least along one direction.

The compliant electrodes are arranged on the deformable sheet in such a way that deformation of the deformable sheet causes the capacitance of the capacitor to vary. The compliant electrodes are preferably positioned on opposing sides of the deformable sheet, i.e. along the larger dimensions of the deformable sheet. Furthermore, the compliant electrodes are preferably positioned at corresponding positions of the opposing sides, i.e. in such a way that the areas of the electrodes are at least substantially overlapping in case the areas are of substantially the same size. Thereby a capacitor is formed having an area which is substantially equal to the area of the electrodes and a distance between the electrodes which is equal to the thickness of the deformable sheet. Thus, a deformation of the deformable sheet resulting in a variation of the thickness of the deformable sheet will in turn result in a variation of the capacitance of the capacitor. Such a deformation may advantageously be provided by stretching the deformable sheet along one or both of the other dimensions. Due to the preservation of the volume this will result in a decrease in the thickness of the deformable sheet, thereby decreasing the distance between the compliant electrodes. This will, in turn, result in an increase in the capacitance of the capacitor and a decrease in the resonance frequency of the resonance circuit.

Alternatively, the deformation may be provided in such a way that the thickness of the deformable sheet is increased, thereby causing an increase in the distance between the compliant electrodes which in turn results in a decrease in the capacitance of the capacitor and an increase in the resonance frequency of the resonance circuit. Such a deformation may, e.g., be provided by at least partly releasing a stretching tension which was previously applied to the deformable sheet as described above.

The capacitance of the capacitor may be variable across a specific range of capacitances, the resonance frequency of the resonance circuit thereby being variable across a specific range of resonance frequencies. The range may, e.g., be defined by the capacitance of the capacitor when no deformation is applied to the deformable sheet and the capacitance of the capacitor when a predefined maximum deformation is applied to the deformable sheet.

In a preferred embodiment the compliant electrodes are corrugated. They may be corrugated in just one direction in which case the electrodes will only be compliant in that direction and not in a direction being substantially perpendicular to that direction. The corrugation may form a sinusoidal pattern, a triangular pattern, a ‘square wave’ pattern or any other suitable pattern as long as the pattern defines ‘hills’ and ‘valleys’.

The compliant electrodes may be deposited directly onto the deformable sheet, e.g. by means of vapour deposition. One way of depositing the compliant electrodes is described in WO 02/37660. Alternatively, the compliant electrodes may be mechanically attached to the deformable material, e.g. by means of gluing.

The resonance circuit described above may advantageously form part of a sensing element. In this case the variable resonance frequency of the resonance circuit may be used for sensing whether or not a deformation of the deformable sheet is taking place.

In the sensing element the deformable sheet may be arranged on at least one object of deformable material, in which case the deformation of the deformable sheet is provided by varying a pressure applied to the object(s) of deformable material.

As described above the term ‘deformable’ should be understood as an inherent property of the material, and it should be interpreted to mean that a decrease in size of the object along one dimension will result in an increase in size along one or both of the remaining dimensions, and vice versa, i.e. the volume of the object is at least substantially preserved during a deformation of the object.

In one embodiment the deformable sheet may be positioned between two objects of deformable material and attached to them in such a way that when a pressure is applied to one or both of the objects the deformable sheet will either be stretched or relaxed, depending on how the pressure is applied. Stretching the deformable sheet will result in a decrease in the thickness of the deformable sheet as described above. Similarly, a relaxation of the deformable sheet will result in an increase in the thickness of the deformable sheet.

In an alternative embodiment, the deformable sheet may be positioned around an object having an elongated cross section, e.g. an elliptic cross section. Depending on where a pressure is applied to the object, the cross section will become either more or less elongated, and the circumference of the cross section will accordingly become longer or shorter. In case a pressure is applied to the object in such a way that the cross section becomes more elongated, thereby causing the circumference of the cross section to become longer, the deformable sheet will be stretched, and the thickness of the deformable sheet will accordingly decrease. Similarly, in case a pressure is applied to the object in such a way that the cross section becomes less elongated, the thickness of the deformable sheet will accordingly increase. In case the cross section is elliptic it will become more elongated if a pressure is applied to the object in a direction which is substantially perpendicular to the major axis, thereby causing the circumference of the cross section to be more eccentric. Similarly, the cross section will become less elongated if a pressure is applied in a direction which is substantially parallel to the major axis, thereby causing the circumference of the cross section to become more circular.

The deformable material may be an elastomeric material, e.g. as described above. In one embodiment, the material of the object may be the same as the material of the deformable sheet.

The sensing element may be or form part of a pressure sensor. Thus, when a pressure is applied to the object(s) of a deformable material the capacitance of the capacitor, and thereby the resonance frequency of the resonance circuit, will be varied. By measuring the resonance frequency of the resonance circuit it is therefore possible to determine whether or not a pressure has been applied to the sensing element. This may, e.g., be done wirelessly from a remote position, and a wireless pressure sensor has thereby been provided, which is cost effective and easy to manufacture, and it is well suited for mass production for the reasons described above. Therefore the pressure sensor may be used for applications where cost is an issue, e.g. in toys or other objects which may not be too expensive.

According to a second object of the present invention the above and other objects of the present invention are fulfilled by providing a sensing system comprising:
one or more sensing elements according to the first aspect of the present invention,
a sending unit comprising an antenna being adapted to induce an electromagnetic field, at least within the range of resonance frequencies for at least one of the sensing elements,
a receiving unit comprising an antenna being adapted to receive a signal generated by at least one of the sensing elements in response to an electromagnetic signal generated by the sending unit.

The sensing system may function in the following manner. The sending unit induces an electromagnetic field in an area where at least one of the sensing elements is present. The electromagnetic field may vary in frequency in order to ‘scan’ a range of frequencies. When the frequency of the induced electromagnetic field matches the resonance frequency of a sensing element that sensing element will start ‘ringing’, thereby generating and emitting a signal at the resonance frequency. This emitted signal will be received by the receiving unit which thereby notes that the resonance frequency of a sensing element has been matched. It further notes the value of the resonance frequency, and it is thereby possible to determine whether or not the sensing element in question was in an ‘activated state’, i.e. whether or not the deformable sheet of the resonance circuit of the sensing element had been subject to a deformation.

In one embodiment, the range of frequencies of the electromagnetic signal induced by the sending unit may be such that only resonance frequencies of ‘activated’ sensing elements can be matched. In this case, when a response signal is received at the receiving unit, this indicates that a sensing element has been activated. Furthermore, the response signal may provide information relating to which sensing element has been activated. The sending unit may even induce a single frequency electromagnetic signal (or the frequency may only vary over a very narrow range). In this case only sensing elements having a resonance frequency matching the induced frequency will start ‘ringing’, thereby indicating that a sensing element has been activated.

The information relating to which sensing element has been activated may be provided by a separate identification signal which is generated and emitted by the sensing element along with the ‘ringing signal’. In this case the sensing element may advantageously be in the form of a Radio Frequency Identification (RFID) tag being capable of emitting a significant signal in response to an electromagnetic signal emitted by the sending unit. In this embodiment it is necessary that the sending unit and the receiving unit are each provided with a separate antenna. In this case the sending signal is a signal having a substantially constant amplitude and a variable frequency which is scanned across the frequency range of interest. The RFID tag has the ability to store energy from the resonance circuit and short circuit the resonance circuit in a predefined bit sequence. The receiving antenna will sense a signal having a substantially constant amplitude, but with a weak samplitued modulation according to the bit sequence generated by the RFID tag. In such a system each resonance circuit, having a resonance frequency which is determined by the variable capacitor, will absorb energy at the time when the frequency of the sending signal matches the resonance frequency, and shortly thereafter transmit an ID but code to the sending unit. Thereby the sending unit will be capable of detecting the signal from the sensing element at the time when a bit code arrives, while at the same time identifying from which sensing element the signal originated (by means of the ID bit code).

Alternatively the information may be included in the response signal. This may be achieved by designing the sensing elements in such a way that the resonance frequency of each sensing element is variable across a distinct range of resonance frequencies, the information relating to which sensing element had been ‘activated’ thereby being provided directly by the resonance frequency. However, in this case the possible number of sensing elements is limited, probably in the order of 4-16, for practical reasons. Another important feature of this approach is that the ‘ringing signal’ will normally be relatively weak. Therefore the sending unit may operate in the following manner. In order for the received signal not to be disturbed by the sending signal, the sending signal should be in the form of short bursts or pulses of sending signal with ‘silent’ pauses between, where the weak ringing signal can be detected. The duration of such a burst is related to the resonance frequency, fres, to be detected and the Q-value of the resonance circuit to be detected. The duration should be 1-3 times Q/fres in order for the resonance circuit to absorb a sufficient amount of energy without losing sampling rate. The ‘silent’ intervals between the sending bursts should be of a similar duration, Q/fres, in order for the resonance circuit to transmit most of the absorbed energy and thereby obtain the best possible signal-to-noise ratio.

The sending unit and the receiving unit may form a single device, or at least the same antenna may be used for emitting the electromagnetic signal generated by the sending unit and for receiving the signal generated by the sensing element. This principle of antenna sharing and switching is known from radio communication systems.

The sending unit may be adapted to generate a series of bursts of electromagnetic signals of varying frequency covering the range(s) of resonance frequencies of the one or more sensing elements. Thereby the sending unit may be capable of individually exciting the current resonance frequency of each of the one or more sensing elements. It will also be possible to determine whether or not the sensing elements have been activated.

The sending unit may comprise a gated Voltage Controlled Oscillator (VCO) and an amplifier for generating and amplifying the electromagnetic signals. However, the sending unit may be constructed in any other suitable way as long as it is designed to provide a signal which suits the needs of the specific application.

Furthermore, the receiving unit may comprise at least one amplifier for amplifying the signal generated by the sensing element(s). This is advantageous because the signal generated by the sensing element(s) may be relatively weak, and it is therefore desirable to amplify it in order to extract the relevant information there from.

Alternatively or additionally, the receiving unit may comprise at least one limiter for limiting a signal generated by the sending unit and received at the receiving unit. Very often the signal generated by the sending unit and received at the receiving unit will be considerably stronger than the signal generated by the sensing element(s) in response to the signal emitted by the sending unit (i.e. the ‘ringing signal’). In order to be able to detect the signal generated by the sensing element(s) it may therefore be desirable to limit the signal originating directly from the sending unit.

Thus, the receiving unit may comprise a plurality of cascade coupled limiters and amplifiers for amplifying the signal generated by the sensing element(s) and limiting a signal generated by the sending unit and received at the receiving unit. In this case the ‘desired’ signal is enhanced while the ‘undesired’ signal is limited, thereby improving the possibilities of extracting relevant information from the received signals.

The sensing system may comprise a plurality of sensing elements, each having a resonance frequency being variable across a range of resonance frequencies, and each being adapted to generate and emit an identification signal being specific for that sensing element in response to an electromagnetic signal generated by the sending unit, thereby forming a distinct response signal. As described above, the sensing elements may in this case advantageously be or form part of a RFID tag being capable of generating the identification signal in addition to the response signal. In this case the sensing system should be designed in such a way that each tag of the system is provided with a unique code, i.e. each tag should be capable of generating and emitting an identification signal which is distinct from an identification signal generated and emitted by the any of the other tags of the system.

Alternatively, the identification information may be present in the response signal, e.g. in the form of distinctive resonance frequencies for each sensing element as described above.

The sensing system may further comprise means for actuating an external device in response to a response signal received at the receiving unit. In this case the sensing system functions as a wireless actuation system for the external device. In case the sensing system comprises two or more sensing elements, each sensing element may represent a specific function of the external device, and activating a sensing element will result in the device performing a corresponding action. Furthermore, the receiving unit may be able to detect to what extent a sensing element has been activated, i.e. to what extent the deformable sheet has been deformed. In this case the corresponding action may advantageously be position control, displacement control, a volume control, acceleration control or a velocity control, and the degree of activation will determine the position, the displacement, the volume, the acceleration or the velocity of the external device.

Thereby a wireless sensing system has been provided which is cost effective to manufacture. This opens the possibility for using the wireless sensing system in relatively low cost products, such as toys, joysticks, remote controls, pressure control systems, etc.

Thus, in case the sensing system comprises a plurality of sensing elements, each having a resonance frequency being variable across a range of resonance frequencies, and each being adapted to generate and emit an identification signal being specific for that sensing element in response to an electromagnetic signal generated by the sending unit, thereby forming a distinct response signal, the means for actuating an external device may be adapted to actuate a plurality of distinct devices and/or a plurality of distinct functions of an external device in response to corresponding distinct response signals received at the receiving unit and originating from distinct sensing elements.

The means for actuating an external device may comprise means for processing a received signal into an actuation signal. Thus, in case the receiving unit receives a signal indicating that a specific sensing element has been activated, it may generate a signal for the external device which is capable of initiating a corresponding action in the external device. Furthermore, in case the receiving unit notes a change in the deformation of the deformable sheet, corresponding to a change in the ‘degree of activation’, it may generate a signal being capable of initiating a corresponding change in the external device, e.g. a change in position, displacement, velocity, acceleration or volume.

The processing means may comprise a microcontroller for interpreting the received signal and generating the actuation signal based on the interpretation.

The means for actuating an external device may form part of the receiving unit. Alternatively they may form part of the external device, or they may be a separate part.

In one embodiment at least part of the sensing system may be adapted to be positioned on or adjacent to an external structure in such a way that the sensing system is adapted to detect a displacement in the external structure. In case the sensing system comprises two or more sensing elements, the system may be positioned in such a way that each sensing element may sense displacements in a specific position of the structure. In this case it is necessary to be able to determine at which position a displacement occurs, i.e. in which sensing element a change in resonance frequency is occurring. This may be achieved as described above.

An example of an application of a sensing system as described above is a system for monitoring cracks, e.g. in walls or on a bridge. In this case sensing elements may be positioned at various positions on the wall or bridge, either randomly or in positions where cracks are known to be present or expected to occur. In case a crack occurs or grows larger in a position corresponding to a sensing element, the deformable sheet of that sensing element will be stretched by the crack, and the resonance frequency will change accordingly. Thereby it may be detected from a remote position that a crack is occurring or growing, and it will also be possible to determine the position of the crack. Thereby the crack may be mended before serious damage is applied to the structure.

The actual states of the sensing systems could the from time to time be registered by scanning them, e.g. from a helicopter. The advantage of these sensing systems is, that they are consistent to conditions like the weather, they are cheap and don't need any electricity since the power to activate them comes from the pulses from the sender.

Alternatively, the sensing system may be positioned on or adjacent to a soft object, e.g. a body part, such as wrapped around an arm or a leg of a person. When the person uses the body part, the volume of the body part (or at least the cross sectional area of the part of the body part where the sensing system is positioned) might change. Such a change will cause the deformable sheet to be stretched or relaxed (depending on whether the volume increases or decreases), and it will therefore be detectable. Thereby a strain in the soft object can be measured.

According to a third aspect of the present invention the above and other objects are fulfilled by providing a position sensitive pressure sensor comprising a plurality of pressure sensitive elements arranged on a two-dimensional structure, each pressure sensitive element comprising a resonance circuit comprising a coil and a capacitor having a capacitance which is variable in response to a variation in a pressure applied to the pressure sensitive element, the corresponding resonance circuit thereby having a variable resonance frequency, each pressure sensitive element further being adapted to generate and emit an identification signal being specific for that element in response to an electromagnetic signal, a measured response signal thereby providing a measure for a pressure applied to a specific position of the two-dimensional structure.

Using a position sensitive pressure sensor as defined above it is possible to determine at which positions a pressure is applied, since the position of each pressure sensitive element is known, and since the response signal is distinct for each pressure sensitive element. Furthermore, it may be possible to determine how much pressure is applied at each position, since this will be reflected by the received resonance frequencies.

The plurality of pressure sensitive elements may be arranged in a predefined two-dimensional pattern, such as a two-dimensional array.

In a preferred embodiment at least one of the pressure sensitive elements is a sensing element as described in connection with the first aspect of the invention. All of the pressure sensitive elements may even be such sensing elements.

The two-dimensional structure may be a piece of flexible material, such as a blanket, a carpet or a mat. In this case it will be possible to determine at which locations of the blanket, carpet or mat a pressure is applied, and it may thereby be possible to determine where and/or how a specific object is positioned.

It should be understood that features described in combination with the first aspect of the present invention may also be combined with the second and third aspects of the present invention, features described in combination with the second aspect of the present invention may also be combined with the first and third aspects of the present invention, and feature described in combination with the third aspect of the present invention may also be combined with the first and second aspects of the present invention.

### BRIEF DESCRIPTION OF THE DRAWINGS

The invention will now be described with reference to the accompanying drawings, in which:

FIG. 1 is a schematic view of a sensing system according to an embodiment of the present invention,

FIG. 2 shows sensing system according to an embodiment of the present invention implemented in a toy,

FIG. 3 shows a position sensitive pressure sensor according to an embodiment of the present invention,

FIGS. 4 and 5 show two ways of forming a sensing element according to the present invention, and

FIG. 6 shows a sensing system according to an embodiment of the present invention positioned on a wall structure.

### DETAILED DESCRIPTION

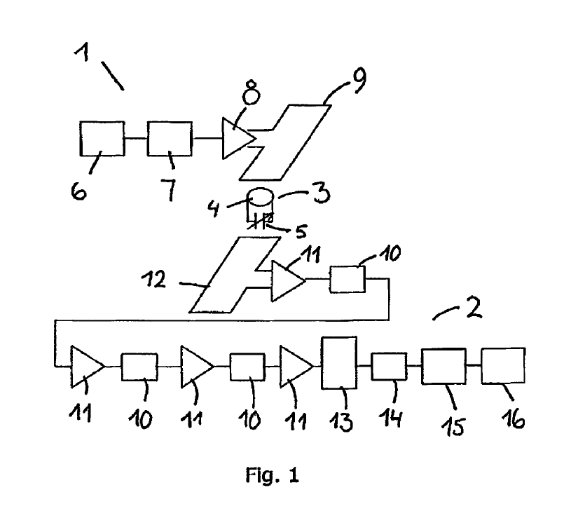

FIG. 1 is a schematic view of a sensing system according to the present invention. The sensing system comprises a sending unit 1, a receiving unit 2, and a sensing element 3. The sensing element 3 comprises a coil 4 and a variable capacitor 5. The variable capacitor 5 has compliant electrodes which are arranged on a deformable sheet as described above. The coil 4 and the variable capacitor 5 in combination form a resonance circuit having a variable resonance frequency.

The sending unit 1 comprises a timer ramp 6 serially connected to a gated Voltage Controlled Oscillator (VCO) 7, which is in turn serially connected to an amplifier 8 for amplifying a signal generated by the VCO 7. The amplified signal is emitted via an antenna coil 9, thereby generating an electromagnetic field in an area where the sensing element 3 is present. The frequency of the emitted signal may be varied, and when the emitted frequency matches the current resonance frequency of the resonance circuit of the sensing element 3, the resonance circuit will generate a response signal at the resonance frequency.

The receiving unit 2 comprises a series of cascade coupled limiters 10 and amplifiers 11 connected to an antenna coil 12 adapted to receive an electromagnetic signal. The antenna coil 12 will pick up the signal emitted by the sending unit 1 as well as any signal generated by the sensing element 3. Since the signal emitted by the sending unit 1 is normally much stronger than signals generated by the sensing element 3, and since we are interested in deriving information from the latter, it is necessary to enhance the signal generated by the sensing element 3 as compared to the signal emitted by the sending unit 1. In the receiving unit 2 shown in FIG. 1 this is achieved by means of the cascade coupled limiters 10 and amplifiers 11. The limiters 10 limit the signal originating directly from the sending unit 1, and the amplifiers 11 amplify the signal generated by the sensing element 3. The limited/amplified signal then undergoes various signal processing by means of a bandpass filter 13, a rectifier 14, an integrator 15 and an analog-to-digital converter (ADC) 16. This processing leads to the derivation of the resonance frequency of the sensing element 3.

The resulting signal may, e.g., be passed on to a microcontroller (not shown) for further processing, e.g. in order to use the result for activating one or more functions of an external device.

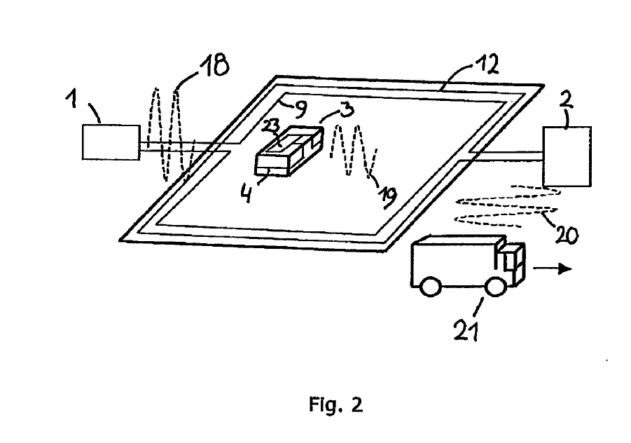

FIG. 2 shows a sensing system which has been implemented in a toy. The sensing system comprises a sending unit 1 and a receiving unit 2. The sending unit 1 is provided with an antenna coil 9 which is adapted to emit an electromagnetic signal generated by the sending unit 1. Similarly, the receiving unit 2 is provided with an antenna coil 12 which is adapted to receive an electromagnetic signal. The antenna coils 9, 12 are positioned in such a way that they cover a large overlapping area. Within this area a sensing element 3 is positioned. The sensing element 3 has a pair of compliant electrodes positioned on a deformable sheet 23, and the sheet 23 is positioned on an object 17 made from a deformable material. The compliant electrodes form a capacitor having a variable capacity as described above. It further comprises a coil 4, the coil 4 and the capacitor in combination forming a resonance circuit having a variable resonance frequency. The capacity of the capacitor is varied by deforming the object 17, thereby stretching the sheet 23 carrying the compliant electrodes. Thereby the sensing element 3 may be ‘activated’ by applying a pressure to the object 17.

The sensing system of FIG. 2 preferably functions in the following manner. The sending unit 1 generates and emits an electromagnetic signal 18. The frequency of the emitted signal 18 may be varied in order to ‘scan’ a range of frequencies so as to attempt to match a possible resonance frequency of the sensing element 3. In case the resonance frequency of the sensing element 3 is matched, the sensing element 3 will start ‘ringing’, thereby emitting an electromagnetic response signal 19 indicating that the resonance frequency has been matched. This response signal 19 is detected by the antenna coil 12 of the receiving unit 2. The antenna coil 12 of the receiving unit 2 is also capable of detecting the electromagnetic signal 18 which was emitted by the sending unit 1. Thereby, the receiving unit 2 will ‘know’ that the resonance frequency of the sensing element 3 has been matched, and at which frequency the resonance frequency has been matched. It is, thus, possible to determine whether or not the sensing element 3 had been activated and possibly to what extent the sensing element 3 had been activated. This information may subsequently be converted by the receiving unit 2 into an activation signal 20 for an external device 21. In FIG. 2 the external device 21 is shown in the form of a toy truck. The activation signal 20 may comprise a command for the external device 21 to perform a specific action corresponding to the state of the sensing element 3. Thus, in the example of FIG. 2 the truck may be caused to start or stop moving, alter the speed, turn right or left, reverse the direction of movement, flash one or more lights, make a sound, etc.

Thereby a wireless actuation system has been provided for the toy truck 21, so that the truck 21 may be controlled by pushing the sensing element 3. In case more sensing elements 3 were present in the area, a number of functions of the truck 21 could be controlled wirelessly by means of the system. This however is just one example of an actuation system, any possible imaginable actuation means a may be applied, wired or wireless.

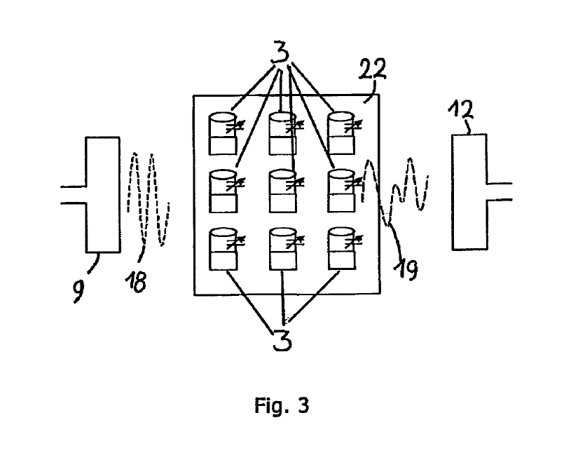

FIG. 3 shows a position sensitive pressure sensor according to an embodiment of the present invention. The sensor comprises a sending unit (not shown) having an antenna coil 9 being adapted to emit an electromagnetic signal 18 which has been generated by the sending unit. The sensor further comprises a receiving unit (not shown) having an antenna coil 12 being adapted to receive a response signal generated by one or more sensing elements 3. Finally, the sensor comprises a flexible structure 22 having nine sensing elements 3 arranged thereon. Each of the sensing elements 3 has a resonance frequency which can be varied within a range, and each sensing element 3 is adapted to generate and emit an identification signal which is specific for each sensing element 3 in response to an electromagnetic signal 18 generated and emitted by the sending unit. Thereby it will be possible to identify which of the sensing elements 3 has had its resonance frequency matched.

When the electromagnetic signal 18 is emitted by the antenna coil 9 the sensing elements 3 will detect the signal 18, and when the frequency of the emitted signal 18 matches the resonance frequency of one of the sensing elements 3, this sensing element 3 will start ‘ringing’, thereby emitting a response signal and an identification signal. This will result in a total response signal 19 comprising the ringing signal as well as the identification signal generated and emitted by the sensing element 3 in question. Thus, the total response signal will carry information that a resonance frequency of one of the sensing elements 3 has been matched, and at which frequency the match occurred. Furthermore, since each of the sensing elements 3 has a specific identification signal, it is possible for the receiving system to derive information from the total response signal 19 relating to which sensing element 3 has had its resonance frequency matched, and whether or not (and possibly to what extent) the sensing element 3 had been activated. Since the sensing elements 3 are arranged on the flexible structure 22 in a known manner, the derived information can easily be transformed into information relating to the position of an object causing one or more sensing elements 3 to be activated.

The sensing elements 3 may advantageously be in the form of Radio Frequency Identification (RFID) tags. This has been described above.

In an related example, sensing elements (with or without RFID tags) 3 are situated in the tires of a vehicle to sense the pressures in the tires.

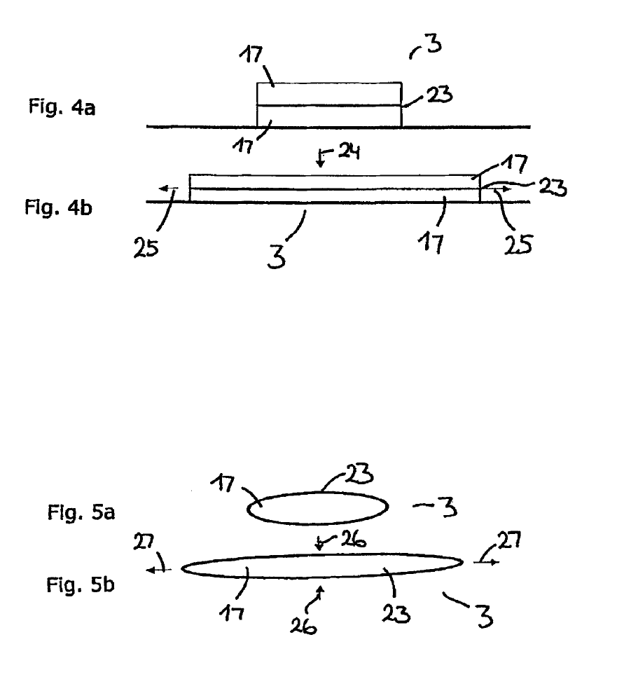

FIG. 4 shows one way of forming a sensing element 3 according to an embodiment of the present invention. A deformable sheet 23 having a pair of compliant electrodes (not shown) arranged thereon on opposing sides as described above is positioned between two objects 17 made from a deformable material. The electrodes form a capacitor. In FIG. 4a the sensing element 3 is shown in a ‘relaxed’ state, i.e. in a state where no external pressure is applied to the objects 17. In FIG. 4b a pressure is applied to the objects 17 in the direction indicated by the arrow 24. This pressure causes the objects 17 to be deformed in such a manner that the size of the objects 17 along direction 24 is decreased. Due to the volume preservation this in turn causes the size of the objects 17 to increase along the directions indicated by arrows 25. The effect is exaggerated in the Figure. The deformable sheet 23 is attached to the objects 17 in such a way that this deformation causes the sheet 23 to be stretched as can be seen in FIG. 4b. Due to volume preservation this in turn causes the thickness of the sheet 23 to decrease, the compliant electrodes thereby being moved closer to each other, the capacity of the capacitor thereby increasing. When the pressure is no longer applied to the objects 17 these will restore, and the capacity of the capacitor will accordingly decrease again.

FIG. 5 shows an alternative way of forming a sensing element 3 according to an embodiment of the present invention. A deformable sheet 23 is arranged around an object 17 made from a deformable material. The deformable sheet 23 has a pair of compliant electrodes (not shown) arranged on opposing sides thereof. The electrodes form a capacitor. In FIG. 5a the sensing element 3 is shown in a ‘relaxed’ state, i.e. a state where no external pressure is applied to the object 17. In FIG. 5b a pressure is applied to the object 17 in the direction indicated by arrows 26. Thereby the size of the object 17 is decreased along directions 26 and increased along the directions indicated by arrows 27. This deformation causes the cross section of the object 17 to become more eccentric, and the circumference of the cross section of the object 17 therefore becomes longer. This will cause the deformable sheet 23 to be stretched, thereby decreasing the thickness of the sheet 23 and increasing the capacity of the capacitor. The effect of the deformation is exaggerated in the Figure.

It should be understood that, alternatively, FIGS. 4b and 5b may represent a ‘relaxed’ state of the sensing element 3, and FIGS. 4a and 4b may represent a state in which a pressure is applied to the object(s) 17 along a direction opposite to the direction indicated by arrows 25, 27, respectively. The resulting deformation will result in an increase in the thickness of the deformable sheet 23 and a corresponding decrease in the capacity of the capacitor.

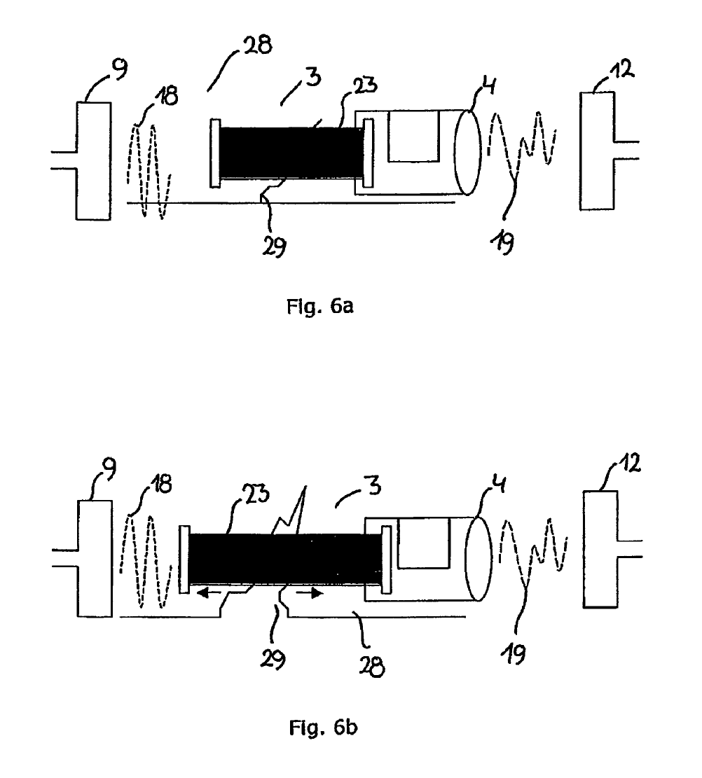

FIG. 6 shows a sensing system according to an embodiment of the present invention. The sensing system is positioned on a wall structure 28 and is adapted to monitor a crack 29 occurring in the wall structure 28. A deformable sheet 23 is positioned across a crack 29. The deformable sheet 23 has a pair of electrodes (not shown) arranged on opposing sides thereof, the electrodes forming a capacitor. The capacitor and a coil 4 in combination form a resonance circuit. In FIG. 6a the crack 29 is very small, but in FIG. 6b it has grown somewhat larger. Thereby the deformable sheet 23 is being stretched, and the thickness of the sheet 23 is decreased due to volume preservation. As described above, the capacity of the capacitor will thereby be increased leading to a decrease in the resonance frequency of the resonance circuit.

An antenna coil 9 emits an electromagnetic signal 18. When the frequency of the emitted signal 18 matches the resonance frequency of the resonance circuit, the resonance circuit will start ringing, thereby emitting a response signal 19 comprising the ringing signal and an identification signal as described above. It is thereby possible to detect, using a receiving antenna 12, whether or not and to what extent the deformable sheet 23 has been stretched by the crack 29. And in case two or more deformable sheets 23 have been positioned at various positions of the wall structure 28 it will also be possible to determine the position of a detected displacement. This is very advantageous because it opens the possibility of monitoring a structure (e.g. a wall structure 28) in order to discover any displacements occurring in the structure, e.g. in the form of cracks 29. Thereby undesired displacements may easily be detected at an early stage, thereby avoiding serious damage to the structure.

In any of the embodiments, the antenna (9) of at least one sending unit (1) and the antenna (12) of the at least one receiving unit (2) may the same antenna element thus operating both as sending unit (1) and receiving unit (2).

In any of the embodiments, there might be a plural of antenna sets of sending units (1) and receiving units (2) (or in the case where the antenna (9, 12) is the same for the sending unit (1) and the receiving unit (2), a antenna set is one such common antenna (9, 12)). This for example could be utilized by positioning such antenna sets in a manner where they each scans a spatial zone. In this manner, not only the actual resonance frequency of sensing elements 3 is measured, but also the actual spatial position(s), at least given within the areas of the zones. In an related embodiment, at least three such antenna sets is positioned, an by comparing the relative strengths of the signals measured scanning the resonance frequency of sensing elements 3, may then be used to estimate the actual spatial positions.

Although various embodiments of the present invention have been described and shown, the invention is not restricted thereto, but may also be embodied in other ways within the scope of the subject-matter defined in the following claims.

What is claimed is:

1. A sensing system comprising:
one or more sensing elements including a capacitor with a variable capacitance at least one sending unit comprising an antenna being adapted to induce an electromagnetic field, at least within the range of resonance frequencies for at least one of the sensing elements, and/or at least one receiving unit comprising an antenna being adapted to receive a signal generated by at least one of the sensing elements in response to an electromagnetic signal generated by the sending unit.

2. The sensing system according to claim 1, where the sensing element is a resonance circuit comprises:
a coil,
the capacitor comprising a set of compliant electrodes arranged on a deformable sheet in such a way that deformation of the deformable sheet causes the capacitance of the capacitor to vary, thereby varying the resonance frequency of the resonance circuit.

3. The sensing system according to claim 2, wherein the deformable sheet is made from an elastomeric material.

4. The sensing system according to claim 1, wherein the capacitance of the capacitor is variable across a specific range of capacitances, the resonance frequency of the resonance circuit thereby being variable across a specific range of resonance frequencies.

5. The sensing system according to claim 1, wherein the compliant electrodes are corrugated.

6. The sensing system according to claim 5, wherein the deformable sheet is arranged on at least one object of deformable material, and wherein the deformation of the deformable sheet is provided by varying a pressure applied to the object(s) of deformable material.

7. The sensing element according to claim 6, wherein the deformable material is an elastomeric material.

8. The sensing element according to claim 5, wherein the sensing element is or forms part of a pressure sensor.

9. The sensing element according to claim 2, wherein the deformable sheet is in-compressible meaning the volume of the deformable sheet substantially is preserved the substantial deformation of the deformable sheet thus being due to a change i shape.

10. The sensing system according to claim 9, wherein the deformation of the deformable sheet is provided by stretching the deformable sheet.

11. The sensing system according to claim 1, wherein the sending unit is adapted to generate a series of bursts of electromagnetic signals of varying frequency covering the range(s) of resonance frequencies of the one or more sensing elements, the sending unit thereby being capable of individually exciting the current resonance frequency of each of the one or more sensing elements.

12. The sensing system according to claim 1, comprising a plurality of sensing elements, each having a resonance frequency being variable across a range of resonance frequencies, and each being adapted to generate and emit an identification signal being specific for that sensing element in response to an electromagnetic signal generated by the sending unit, thereby forming a distinct response signal.

13. The sensing system according to claim 1, further comprising means for actuating an external device in response to a response signal received at the receiving unit.

14. The sensing system according to claim 13, the sensing system comprising a plurality of sensing elements, each having a resonance frequency being variable across a range of resonance frequencies, and each being adapted to generate and emit an identification signal being specific for that sensing element in response to an electromagnetic signal generated by the sending unit, thereby forming a distinct response signal, wherein the means for actuating an external device is adapted to actuate a plurality of distinct devices and/or a plurality of distinct functions of an external device in response to corresponding distinct response signals received at the receiving unit and originating from distinct sensing elements.

15. The sensing system according to claim 13, wherein the means for actuating an external device comprises means for processing a received signal into an actuation signal.

16. The sensing system according to claim 15, wherein the processing means comprises a microcontroller.

17. The sensing system according to claim 13, wherein the means for actuating an external device form part of the receiving unit.

18. The sensing system according to claim 1, wherein at least part of the sensing system is adapted to be positioned on or adjacent an external structure in such a way that the sensing system is adapted to detect a displacement in the external structure.

19. A position sensitive pressure sensor comprising a plurality of pressure sensitive elements arranged on a two-dimensional structure, each pressure sensitive element comprising a resonance circuit comprising a coil and a capacitor having a capacitance which is variable in response to a variation in a pressure applied to the pressure sensitive element, the corresponding resonance circuit thereby having a variable resonance frequency, each pressure sensitive element further being adapted to generate and emit an identification signal being specific for that element in response to an electromagnetic signal, a measured response signal thereby providing a measure for a pressure applied to a specific position of the two-dimensional structure.

20. The position sensitive pressure sensor according to claim 19, wherein the plurality of pressure sensitive elements are arranged in a predefined two-dimensional pattern.

21. The position sensitive pressure sensor according to claim 20, wherein the predefined two-dimensional pattern is a two-dimensional array.

22. The position sensitive pressure sensor according to claim 19, wherein at least one of the pressure sensitive elements is a sensing element according to claim 1.

23. The position sensitive pressure sensor according to claim 19, wherein the two-dimensional structure is a piece of flexible material.

24. The sensing system according to claim 1, wherein the antenna of at least one sending unit and the antenna of the at least one receiving unit is the same antenna element thus operating both as sending unit and receiving unit.

25. The sensing system according to claim 1, comprising a plural of sending units and/or receiving units.
